(19) United States
(12) Patent Application Publication
(10) Pub. No.: US 2006/0202221 A1
(43) Pub. Date: Sep. 14, 2006

(54) LED

(76) Inventor: Martin Klenke, Blieskastel (DE)

Correspondence Address: NEEDLE & ROSENBERG, P.C., SUITE 1000, 999 PEACHTREE STREET, ATLANTA, GA, 30309-3915, US

(21) Appl. No.: 11/367,239

(22) Filed: Mar. 3, 2006

Related U.S. Application Data
(60) Provisional application No. 60/691,707, filed on Jun. 17, 2005.

(30) Foreign Application Priority Data
Mar. 10, 2005 (EP) 05 005 252.1

(51) Int. Cl. H01L 33/00

(52) U.S. Cl. 257/98

(57) ABSTRACT

A LED comprises a base body. The base body carries a light generating element. A light guide body is provided in the emitting direction of the light generating element. According to the invention, the light guide body comprises diffractive groups of light guide elements to fix the emission angle of the LED.

### CROSS REFERENCE TO RELATED APPLICATIONS

This application claims priority to European patent application No. 05 005 252.1 filed on Mar. 10, 2005, and to U.S. provisional patent application No. 60/691,707 filed Jun. 17, 2005, which applications are hereby incorporated by this reference in their entireties.

### BACKGROUND OF THE INVENTION

The invention refers to a LED.

LED's, i.e. light emitting diodes, are used in a variety of devices and find widespread use today. Depending on the materials used, an LED generates light in different colors, both in the visible and the non-visible range. A light guide body is associated to this light generating element in the emitting direction. The emission angle of the LED is determined by the light guide body which is most often made of plastic material. Known light guide bodys are refractive elements such as lenses, for example. The refraction of the light emitted by the light generating element caused by refractive light guide elements results in that the light emission properties can not well be corrected. In particular, no good beam collimation is possible. Since refractive elements are lenses, in particular, which always show marginal aberrations, the errors increase when the individual lenses are miniaturized, since a plurality of small lenses has more margins than one large lens.

It is the object of the invention to provide an LED with good emission properties.

### SUMMARY OF THE INVENTION

The LED of the present invention comprises a base body carrying the light generating element, such as a LED chip. A light guide body is arranged in the emitting direction of the light generating element. According to the invention, the light guide body comprises diffractive light guide elements. Providing light guide elements diffracting light has the advantage that an emission angle of the LED can be set in a simple manner with little loss. With the provision of diffractive light guide elements, as suggested by the invention, the light emission properties can be corrected well. In particular, it is possible to realize a good beam collimation. Since, in contrast to refractive elements, diffractive light guide elements have no marginal aberrations, a miniaturization of the individual diffractive light guide elements, as provided by the invention, is possible with good light emission properties.

The configuration of the light guide elements for setting the emitting direction or the emission angle, respectively, is obtained by a corresponding configuration of the diffraction gratings provided in the light guide elements. Here, the diffraction level of the diffraction gratings can be determined using the Fraunhofer diffraction law.

Preferably, the light guide elements are arranged at a surface of the light guide body. The surface may be the surface facing the light generating element or the opposite surface. It is further possible to dispose light guide elements such as reflectors and the like between the light generating element and the light guide body so that the surface provided with the light guide elements is directed towards the reflector, for example.

Here, it is particularly preferred to make the light guide elements using a curing lacquer on the surface of the light guide body. For this purpose, a forming means is preferably used in which the negative of the diffraction grating is formed by lithographic methods, for example. Using a single forming means, a plurality of light guide elements can preferably be duplicated. To do so, a curing lacquer is preferably used that establishes a stronger bond with the light guide body than with the forming means. Thus, it is ensured that an exact surface pattern is formed when the forming means is removed.

A particularly preferred method of production as well as a suitable material for making the light guide elements is described in EP 05 003 358.8.

A material particularly suitable for making the surface elements is:

11 g 1H,1H,2H,2H-perfluoro octyle acrylate were mixed with 8 g dipropylene glycol diacrylate, 0.1 g Irgacure® 819 and 0.2 g Irgacure® 184 sold by Ciba Spezialitätenchemie Lampersheim GmbH. 60 μl of this mixture were applied on a nickel plate of 2 by 2 cm, whose surface was patterned with a negative form of a mold body with scattering centers. Subsequently, a small plate of PMMA, being 1 mm thick and 1 by 1 cm in size, was applied on the surface of the mixture on the nickel plate. Thereafter, the sandwich thus obtained on the nickel plate with the mixture therebetween was subjected to 2 seconds of UV radiation from a conventional quicksilver lamp. Then, the substrate with the cured forming compound bonded thereto was removed from the negative mold.

To be able to define an exact position of the individual light guide elements on the surface of the light guide body, the surface provided with the light guide elements is preferably flat.

Preferably, the individual light guide elements are configured such that they act as diffractive elements that preferably generate a collimated light bundle with spectral light splitting. For this purpose, the individual light guide elements preferably comprise surface structures that are wave-shaped in cross section, the pitch between the waves being selected as a function of the wavelength to be deflected. Preferably, individual light guide elements have different diffraction gratings. It is particularly preferred to arrange the light guide elements such that mostly monochromatic light and/or white light is produced by superposing at least two adjacent light bundles. Here, monochromatic light refers to a wavelength range of ±100 nm, in particular ±50 nm. Providing such light guide elements, as suggested by the invention, a mostly monochromatic and/or white light, in particular collimated light can thus be generated.

The configuration of the surface of the light guide elements further allows to adjust the emitting direction of the light from the display surface. To this avail, the diffraction grating provided on the surface elements must be modified according to Fraunhofer's diffraction laws. Preferably, the adjustability range is from 0-90° with respect to the display surface.

It is also possible to adjust the color temperature of the emitted light depending on the choice or the configuration of the structure/pattern? of the light guide elements. Preferably, it is possible to adjust the color temperature in a range from 3000 K-10,000 K.

In particular, a spectral splitting is avoided or substantially reduced, due to the present configuration of the display surface with diffractive surface elements. Further, a sufficient light amplification is ensured, while the energy consumption is low.

The present diffractive light guide elements preferably have a size of 0.04 μm² to 10,000 μm², in particular 0.04 μm² to 500 μm². Because such small surfaces are provided, it is possible to provide a plurality of surface elements even in very small flat screens such as displays for mobile applications. Here, the distance between individual light guide elements preferably lies in the range from 0 to 100 μm, in particular from 0 to 50 μm, and, most preferred, from 0 to 15 μm. It is particularly preferred that the light guide elements have a mutual distance >0. Preferably, the distance is at least 1 μm, in particular at least 3 μm. This has the advantage that the distance between the light guide elements can be decreased in areas, where more light is to be coupled out, whereas in areas, where a smaller amount of light is to be coupled out, larger distance can be provided. Thereby, a good uniformity of the distribution of luminosity can be achieved. Further, it is simpler in production to always arrange the individual light guide elements with a mutual distance. When the light guide elements are produced, for example, using a curing lacquer in combination with a forming element or a negative, spacing the light guide elements avoids corruption at the borders of the surface elements caused, e.g., by the occurrence of lacquer webs. Moreover, spacing the individual light guide elements ensures that refractions or corruptions of the diffraction caused by adjoining surface structures are avoided.

Since, according to a preferred embodiment of the invention, the individual light guide elements have the same surface structure in terms of height or amplitude, the diffraction efficiency of the individual light guide elements is identical. Mere production-related variations of a few percent may occur which have only a slight impact on the diffraction efficiency.

It is particularly preferred to configure the individual light guide elements such that the amplitude of the different surface structures is constant and only the frequency is changed. Depending on the type of surface structure, which does not necessarily have to be a sinusoidal surface structure, all raised portions, generally speaking, have the same height, yet have different mutual distances. This results in the fact that light emitted from the light source is diffracted differently by the individual surface elements. In this context, it is particularly advantageous that varying distances are simpler to produce than varying heights.

Preferably, a plurality of light guide elements with different surface structures are comprised in one group of light guide elements. In doing so, the different surface structures are selected such that a group of light guide elements emits substantially monochromatic and/or white light. The type of surface structure, in particular the change in the wavelength of the light caused by the surface structure, is determined depending on the wavelength ranges emitted by the light source.

Preferably, a group of light guide elements comprises at least two light guide elements with different surface structures. Preferably, the group of light guide elements comprises at least four, in particular at least six light guide elements, each having another surface structure.

Since, according to a preferred embodiment of the present invention, the individual light guide elements have the same surface structure in terms of height or amplitude, the diffraction efficiency of the individual light guide elements is identical. Mere production-related variations of a few percent may occur which have only a slight impact on the diffraction efficiency.

It is particularly preferred to configure the individual light guide elements such that the amplitude of the different surface structures is constant and only the frequency is changed. Depending on the type of surface structure, which does not necessarily have to be a sinusoidal surface structure, all raised portions, generally speaking, have the same height, yet have different mutual distances. This results in the fact that light emitted from the light source is diffracted differently by the individual light guide elements. In this context, it is particularly advantageous that varying distances are simpler to produce than varying heights.

The light guide elements preferably arranged in groups of light guide elements, which may be six light guide elements of different surface structures, for example, preferably have the same amplitude of 550 nm. The individual light guide elements of a group of light guide elements have a respective frequency of 490 nm, 503 nm, 517 nm, 530 nm, 575 nm and 620 nm, for example. In particular, the diffractive light guide elements have a sinusoidal surface structure. The distance between the individual light guide elements is preferably in the range from 1 to 100 μm, in particular from 1 to 50 μm and, most preferred, in the range from 1 to 15 μm.

### BRIEF DESCRIPTION OF THE DRAWINGS

In the following, the invention is described in detail by means of a preferred embodiment and with reference to the accompanying drawings.

In the figures:

FIG. 1 is a schematic sectional view of a LED,

FIG. 2 is a schematic top plan view on a light guide body,

FIG. 3 is a schematic perspective view of a light guide element and

FIG. 4 is an example of a possible arrangement of surface elements as groups of surface elements.

### DESCRIPTION OF THE PREFERRED EMBODIMENTS

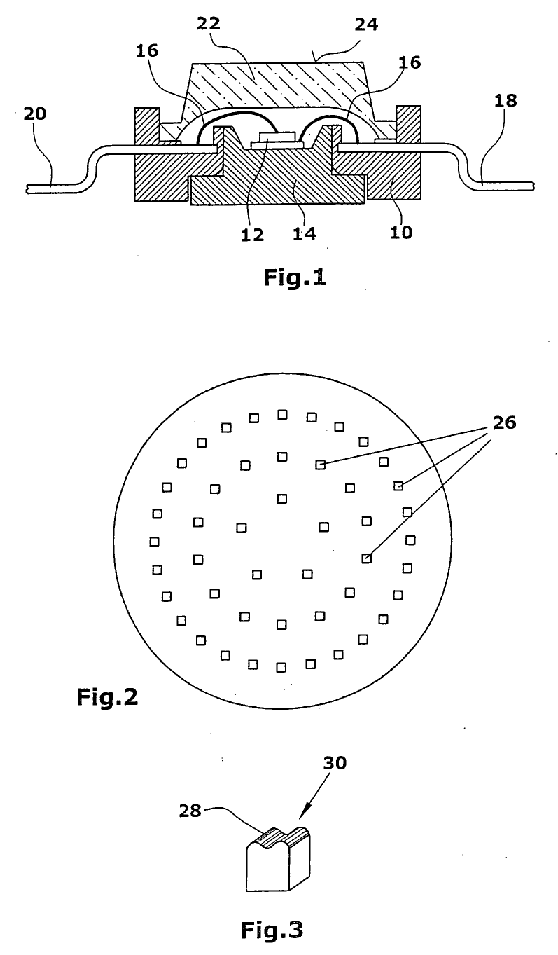

An LED comprises a base body 10 that carries a light generating element 12, such as a LED chip. Possibly, the base body additionally comprises a heat conductor body 14 for cooling the light generating element 12. Lines 16 connect the light generating element 12 with a cathode 18 and an anode 20 in the emitting direction, i.e. upward in FIG. 1, a light guide body 22 is provided. The light guide body 22 is fastened to the base body 10. Groups of diffractive light guide elements 26 (FIG. 2) are arranged on a top surface 24 of the light guide body 22.

The groups of diffractive light guide elements 26 provided according to the invention, which may be arranged in concentric circles on the surface 24, serve to determine the emission angle of a LED. Using correspondingly configured and arranged light guide elements, small emission angles can be realized.

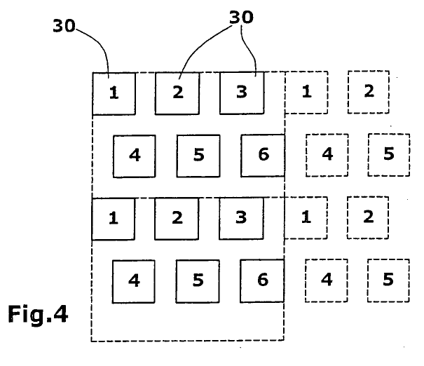

The individual groups of light guide elements 26 comprise a plurality of light guide elements 30. In an embodiment illustrated in FIG. 4, a group of light guide elements 26 comprises six light guide elements 30 preferably disposed with a respective gap therebetween and at a constant distance from each other. Each single light guide element 30 has a different surface structure so that a group of light elements 26 emits substantially monochromatic or white light.

Preferably, to couple out light of different wavelengths, different light guide elements 30 with different surface structures are provided. For example, as in the embodiment illustrated in FIG. 4, these may be six different light guide elements 30 with different surface structures 28. In FIG. 4, the individual different light guide elements 30 are numbered 1-6. Here, the light guide elements 30 given the same number have the same surface structure. Preferably, the light guide elements 30 numbered 1-6 in FIG. 4 are arranged in a repeating pattern.

The surface structure of the single surface elements is preferably sinusoidal. Preferably, the amplitude is 550 nm. The six differently designed light guide elements 30 have the same amplitude. The single light guide elements 30 have frequencies of 490 nm, 503 nm, 517 nm, 530 nm, 575 nm and 620 nm, for example. The distance between the individual light guide elements preferably is in the range from 1 to 100 μm, in particular from 1 to 50 μm and, most preferred, from 1 to 15 μm.

1. LED comprising:
a base body,
a light generating element carried by the base body,
a light guide body arranged in the emitting direction of the light generating element, and
wherein the light guide body comprises diffractive light guide elements.

2. LED of claim 1, wherein the light guide elements are arranged on a surface of the light guide body.

3. LED of claim 2, wherein the light guide elements are made of a curing lacquer applied onto said surface.

4. LED of claim 1, wherein the light guide elements are arranged and/or configured such that the emission angle of the LED is fixed.

5. LED of claim 1, wherein all light guide elements have a surface structure with a constant amplitude.

6. LED of claim 1, wherein the light guide elements have a size between 0.04 and 10,0000 μm².

7. LED of claim 1, wherein the individual light guide elements have a mutual distance of 1 to 100 μm.

8. LED of claim 1, wherein a plurality of light guide elements are comprised in a group of light guide elements, the groups of light guide elements emitting monochromatic and/or white light.

9. LED of claim 6, wherein the light guide elements have a size between 0.04 and 500 μm².

10. LED of claim 7, wherein the individual light guide elements have a mutual distance of 1 to 50 μm.

11. LED of claim 7, wherein the individual light guide elements have a mutual distance of 1 to 15 μm.

12. LED of claim 8, wherein at least four light guide elements are comprised in a group of light guide elements, the groups of light guide elements emitting monochromatic and/or white light.

13. LED of claim 8, wherein at least six light guide elements are comprised in a group of light guide elements, the groups of light guide elements emitting monochromatic and/or white light.
